(19) United States
(12) Patent Application Publication
(10) Pub. No.: US 2026/0150368 A1
(43) Pub. Date: May 28, 2026

(54) Semiconductor Devices and Methods for Manufacturing the Same

(71) Applicant: Infineon Technologies Austria AG, Villach (AT)

(72) Inventors: Anita Brazzale, Villach (AT); Maximilian Rösch, St. Magdalen (AT); Maria Mitronika, Villach (AT); Britta Wutte, Feistritz i. R. (AT); Marija Borna Tutuc, Villach (AT); Magdalena Forster, Bodensdorf (AT); Arnold Marak, Latschach (AT); Thomas Ostermann, Oberwinklern (AT)

(21) Appl. No.: 19/391,471

(22) Filed: Nov. 17, 2025

(30) Foreign Application Priority Data
Nov. 22, 2024 (DE) 102024134370.2
Feb. 10, 2025 (DE) 102025104786.3

(51) Int. Cl. H10D 64/00; H10D 64/01

(52) U.S. Cl. CPC H10D 64/117; H10D 64/01

(57) ABSTRACT

A semiconductor device includes a semiconductor substrate having a first major surface, an active area, and an edge region laterally surrounding the active area. A trench structure formed in the first major surface includes a base, sidewalls, a transverse trench section, and longitudinal trench sections. The transverse trench section is located in the edge region. The longitudinal trench sections extend from the transverse trench section into the active area. The trench structure further includes a field plate electrically insulated from the semiconductor substrate by a dielectric layer located on the base and side walls of the trench structure. The dielectric layer has a thickness t_{end} on the side walls in an end portion of the longitudinal trench sections located in the edge region and has a thickness t_{act} on the side walls in a portion of the longitudinal trench sections located in the active area, where t_{end}>t_{act}.

### TECHNICAL FIELD

The present disclosure relates to semiconductor devices and methods for manufacturing semiconductor devices.

### BACKGROUND

Transistors used in power electronic applications may be fabricated with silicon (Si) semiconductor materials. Common transistor devices for power applications include Si CoolMOS™, Si Power MOSFETs, and Si Insulated Gate Bipolar Transistors (IGBTs).

Some electrically conducting structures integrated into semiconductor devices are electrically insulated from other parts of the device to achieve the desired functioning of the semiconductor device. Examples of such conducting structures are gate electrodes and field plates, also known as field electrodes, which are insulated from the semiconductor substrate by insulation layers such as oxide layers. For example, an electrically conductive field plate may be located in a trench formed in the semiconductor substrate. The field plate is electrically insulated from the semiconductor substrate by an insulating layer, also known as a field dielectric, that lines the trench.

A transistor device for power applications may be based on the charge compensation principle and may include an active cell field including a plurality of elongate trenches, each including a field plate located in a trench for charge compensation. The trenches and the mesas that are formed between adjacent trenches each have an elongate striped structure.

Termination design of a trench power MOSFETs is related to the ruggedness of the device. The mesa termination shape affects managing the electric field distribution at the edge of the active area in power semiconductor devices and different mesa termination shapes can influence the breakdown voltage (BV) of device.

It is desirable to further improve the performance and reliability of semiconductor devices, for example, by further reducing the risk of undesirable electrical breakdown. Methods for fabricating a semiconductor device with good performance are also desirable.

### SUMMARY

In an embodiment, a semiconductor device, comprises a semiconductor substrate comprising a first major surface, an active area and an edge region that laterally surrounds the active area, a trench structure formed in the first major surface and comprising a base, sidewalls, a transverse trench section and a plurality of longitudinal trench sections, wherein the transverse trench section is located in the edge region and the plurality of longitudinal trench sections extend from the transverse trench section into the active area. The trench structure comprises a field plate that is electrically insulated from the semiconductor substrate by a dielectric layer located on the base and the side walls of the trench structure. The dielectric layer has a thickness t_{end} on the side walls in an end portion of the longitudinal trench sections which is located in the edge region and has a thickness t_{act} on the side walls in a portion of the longitudinal trench sections which is located in the active area, wherein t_{end} is greater than t_{act}.

In an embodiment, a semiconductor device, comprises a semiconductor substrate comprising a first major surface, an active area and an edge region that laterally surrounds the active area, a trench structure formed in the first major surface and comprising a base, sidewalls, a transverse trench section and a plurality of longitudinal trench sections, wherein the transverse trench section is located in the edge region and the plurality of longitudinal trench sections extend from the transverse trench section into the active area. The trench structure comprises a field plate that is electrically insulated from the semiconductor substrate by a dielectric layer located on the base and the side walls of the trench structure. The semiconductor substrate has a first conductivity type and a doping level of X of 1×10¹⁶·cm⁻³ to 2×10¹⁷ cm⁻³ in the active region and comprises a doped region of the first conductivity type that has a doping level Y of 1×10¹⁶ cm⁻³ to 2×10¹⁷ cm⁻³. The doped region is located adjacent a lower half of an end portion of the plurality of longitudinal trench sections, the end portion being located in the edge region, wherein 115% X≤Y≤135% X.

In an embodiment, a method comprises forming a trench structure in a first surface of a semiconductor substrate comprising an active area and an edge region that laterally surrounds the active area, wherein the trench structure comprising a base, sidewalls, a transverse trench section and a plurality of longitudinal trench sections, wherein the transverse trench section is located in the edge region and the plurality of longitudinal trench sections extend from the transverse trench section into the active area and forming a dielectric layer on the base and the side walls of the plurality of longitudinal trench sections and the transverse trench section with a thickness t_{end} on the side walls in end portions of the longitudinal trench sections which are located in the edge region and a thickness t_{act} on the side walls in portions of the longitudinal trench sections which are located in the active area, wherein t_{end} is greater than t_{act}.

In an embodiment, a method comprises forming a trench structure in a first surface of a semiconductor substrate of a first conductivity type comprising an active area and an edge region that laterally surrounds the active area, wherein the trench structure comprising a base, sidewalls, a transverse trench section and a plurality of longitudinal trench sections, wherein the transverse trench section is located in the edge region and the plurality of longitudinal trench sections extend from the transverse trench section into the active area and selectively implanting dopants of the first conductivity type into the base of the transverse trench section and into the base of the end portion of the plurality of longitudinal trench sections located in the edge region and forming a doped region of the first conductivity type.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A to 1E illustrate various views of a semiconductor device according to an embodiment.

FIGS. 2A to 2E illustrate views of a semiconductor device according to an embodiment.

FIGS. 3A to 3E illustrate various views of a semiconductor device 10 according to an embodiment.

FIG. 4 illustrates a schematic representation of a T design of a trench termination of a semiconductor device according to an embodiment.

FIG. 5A illustrates exemplarily implants simulations results depicting n-type dopant concentrations at trench and mesa area for different tilts and doses, and FIGS. 5B and 5C illustrate concentration profiles at the mesa top and final phosphorous concentration profiles for different tilt and dose in comparison to a reference.

FIG. 6 illustrates a schematic cross section (A) of the termination during the implantation at a hard mask opening and a schematic cross-section (B) of the termination during the implantation after trench etch.

FIG. 7 illustrates a schematic cross section (A) of the termination during the stage of the implantation and a schematic cross section (B) of the termination during the stage of the implantation according to an alternative embodiment.

FIGS. 8A to 8F illustrate a process for fabricating a field dielectric with an increased thickness in a T-shaped termination region.

FIGS. 9A to 9F illustrate a process for fabricating a doped region with an increased doping concentration at a bottom and sidewalls of a trench according to an embodiment.

FIGS. 10A to 10F illustrate a process for fabricating a doped region with an increased doping concentration at a bottom and sidewalls of a trench according to another embodiment.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing”, etc., is used with reference to the orientation of the figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of exemplary embodiments will be explained below. In this case, identical structural features are identified by identical or similar reference symbols in the figures. In the context of the present description, “lateral” or “lateral direction” should be understood to mean a direction or extent that runs generally parallel to the lateral extent of a semiconductor material or semiconductor carrier. The lateral direction thus extends generally parallel to these surfaces or sides. In contrast thereto, the term “vertical” or “vertical direction” is understood to mean a direction that runs generally perpendicular to these surfaces or sides and thus to the lateral direction. The vertical direction therefore runs in the thickness direction of the semiconductor material or semiconductor carrier.

As employed in this specification, when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

As employed in this specification, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used herein, various device types and/or doped semiconductor regions may be identified as being of n type or p type, but this is merely for convenience of description and not intended to be limiting, and such identification may be replaced by the more general description of being of a “first conductivity type” or a “second, opposite conductivity type” where the first type may be either n or p type and the second type then is either p or n type.

The figures illustrate relative doping concentrations by indicating “−” or “+” next to the doping type “n” or “p”. For example, “n−” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

The trench, in which the field plate is arranged, may have an elongate stripe-like form having a length which extends parallel to the first major surface, its length being greater than its depth from the first major surface and the depth being greater than its width.

The electrodes or terminals of the transistor device are referred to herein as source, drain and gate. As used herein, these terms also encompass the functionally equivalent terminals of other types of transistor devices, such as an insulated gate bipolar transistor (IGBT). For example, as used herein, the term “source” encompasses not only a source of a MOSFET device and of a superjunction device but also an emitter of an insulator gate bipolar transistor (IGBT) device and an emitter of a Bipolar Junction Transistor (BJT) device, the term “drain” encompasses not only a drain of a MOSFET device or of a superjunction device but also a collector of an insulator gate bipolar transistor (IGBT) device and a collector of a BJT device, and the term “gate” encompasses not only a gate of a MOSFET device or of a superjunction device but also a gate of an insulator gate bipolar transistor (IGBT) device and a base of a BJT device.

Some trench MOSFETS have a so-called T-mesa termination design, in which the mesas have an end face which is bounded by a transverse trench that transitions into the longitudinal trench sections defining the width of the mesa. The so-called T-mesa termination has been widely used in various transistor technologies and while there are benefits of using such mesa terminations with respect to design ruggedness, it has also its challenges, such as that the difference in compensation (3D) compared to the active area of the cell, may create a breakdown voltage dependance on the current density.

For low currents, the breakdown voltage (BV) of the device may be limited by the T-mesa termination. The actual breakdown of the cell may be hindered and may be only shown at high currents. This may create a weakness in the device ruggedness limited by the T-mesa termination and may have an impact on the device reliability, for example Vds overshoot in application exceeds the breakdown voltage of the device in a cell designed with too low BV,—device goes in avalanche causing shift of electrical parameters like Rdson etc. Furthermore, in case the BV in the device, e.g. transistor device, depends on the termination, the modeling and assessments of statistics derived from simulations and data analysis based on TCAD models may be limited.

In the technologies where T-mesa termination is used in the design, the BV limitation by the termination may, for example, be addressed, by either overengineering of the cell to compensate for the termination—leading to impact on other electrical parameters that worsen the performance of the device, for example epi engineering with penalty on Rdson etc. or by engineering of testing conditions (whenever possible) to move the BV to the cell field without compromise on device reliability or testing costs.

According to examples of the present disclosure, engineering the compensation in the T-mesa termination is performed via at least one of implants to form the more highly doped region, or a field dielectric thickness increase in the edge region. This may improve the weakness of the termination and/or may allow for an increase in BV of the termination, closer to the real cell breakdown. According to some embodiments, this may allow the BV of the termination to be improved with no or only little influence on the one of the active transistor cells of the transistor device.

The proposed mesa termination may relate to managing the electric field distribution at the edge of the active area as the shape of the end of the mesa provided by the trenches to form the T mesa termination can influence the breakdown voltage of the device. In this specific shape, the compensation from three sides and a narrower mesa can lead to potential lines being squeezed between substrate and trench bottom.

A different approach proposed in this disclosure is to create higher mesa doping at the mesa ending. This can be achieved by the n+ phosphorous implantation at the termination region for n-type semiconductor substrates. In a typical process flow, there are two stages when this additional implantation can be implemented. After the hard mask opening or after the trench etch. Both approaches aim to increase the concentration of phosphorous along the trench in the termination area by, for example, approximately 25%.

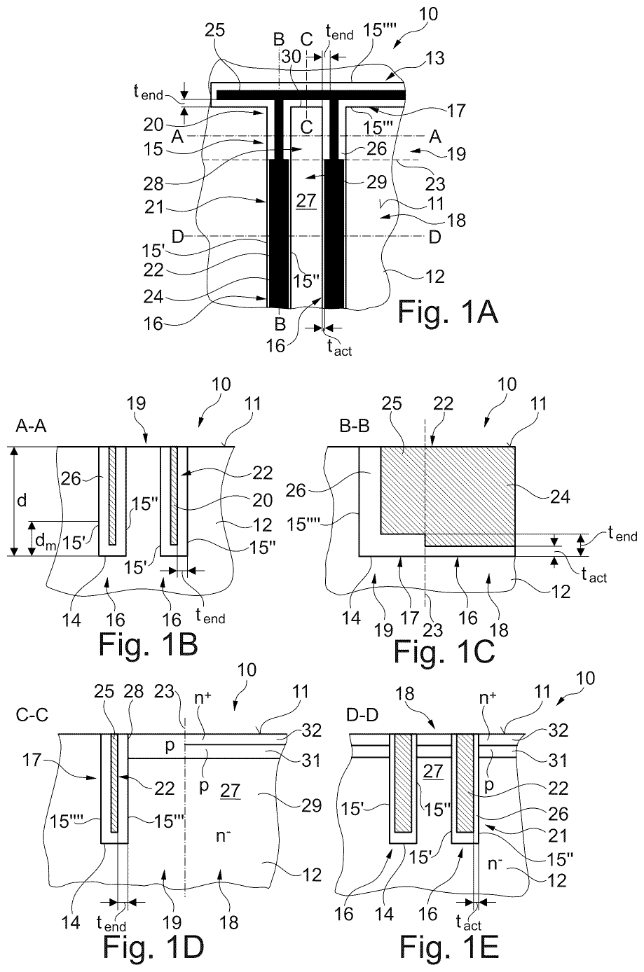

FIGS. 1A to 1E illustrate various schematic views of a semiconductor device 10. FIG. 1A illustrates a plan view of the semiconductor device 10 and illustrates a portion of a first major surface 11 of a semiconductor substrate 12. The semiconductor substrate 12 may have the form of an epitaxial layer, for example an epitaxial silicon layer. The epitaxial layer may be formed on a base substrate, e.g. a single crystal silicon wafer, which is not illustrated in the drawings. A trench structure 13 is formed in the first major surface 11 of the semiconductor substrate 12. FIG. 1B illustrates a cross-sectional view along the line A-A shown in FIG. 1A, FIG. 1C illustrates a cross-sectional view along the line B-B shown in FIG. 1A, FIG. 1D illustrates a cross-sectional view along the line C-C shown in FIG. 1A and FIG. 1E illustrates a cross-sectional view along the line D-D shown in FIG. 1A.

As can be seen in the cross-sectional views of FIGS. 1B to 1E, the trench structure 13 comprises a base 14 and a side wall 15 which extends from the base 14 to the first major surface 11. The trench structure 13 comprises a plurality of longitudinal sections 16, two of which are shown in FIGS. 1A-1E. The longitudinal trench sections 16 have an elongate strip-like structure and extend substantially parallel to one another. The trench structure 13 further includes a transverse trench section 17 which extends substantially perpendicularly to the longitudinal trench sections 16. The transverse trench section 17 also has an elongate stripe-like form. The elongate longitudinal trench sections 16 each have a length which extends parallel to the first major surface 11, the length being greater than its depth from the first major surface 11 and the depth being greater than its width. The elongate transverse trench section 17 has a length which extends parallel to the first major surface 11, the length being greater than its depth from the first major surface 11 and the depth being greater than its width.

The longitudinal trench sections 16 are integral with and extend into the transverse trench section 17 to form the trench structure 13. The longitudinal trench sections 16 are in fluid communication with the transverse trench section 17. The longitudinal trench sections 16 meet the transverse trench section 17 at an angle of about 90° and form a T-shape. The perpendicular arrangement of the longitudinal trench section 16 and transverse trench section 17 has a T-shape in top view.

The terms “longitudinal” and “transverse” are used herein to denote first and second directions that extend perpendicularly to one another. As used in the description of the drawings, longitudinal refers to a vertical direction in the drawings and transverse to a horizontal direction in the drawings. However, the semiconductor device 10 may be rotated so that the longitudinal direction and the transverse direction extend in a non-vertical direction and non-horizontal direction, respectively.

The semiconductor substrate 12 comprises an active area 18 and an edge region 19 which laterally surrounds the active area 18 on all sides. The boundary between the active area 18 and the edge region 19 is shown schematically in the drawings by the dashed line 23. The active area 18 includes device structures, for example transistor device structures. For embodiment in which the semiconductor device 10 comprises a transistor device, the active area 18 has a lateral extent that corresponds to the lateral extent of the source region of the transistor device. The transverse trench section 17 is located in the edge region 19 and the longitudinal trench sections 16 extend from the transverse trench section 17 into the active area 18. The longitudinal trench sections 16, therefore, each include an end portion 20 which is located in the edge region 19 and an active portion 21 which is located in the active area 18 of the semiconductor device.

The trench structure 13 comprises a field plate 22 which is located in the trench structure 13 and which is electrically insulated from the semiconductor substrate 12, in which the trench structure 13 is formed, by a dielectric layer 26 which is located on the base 14 and side walls 15 of the trench structure 13. The field plate 22 has a shape which corresponds to the shape of the trench structure 13. The field plate 22 has longitudinal sections 24 which are located in the longitudinal trench sections 16 and a transverse section 25 which is integral with the longitudinal trench sections 24 and which is located in the transverse trench section 17.

The field plate 22 is electrically insulated from the semiconductor substrate 12 by the dielectric layer 26 which is located on the base 14 and sidewalls 15 of the trench structure 13. The dielectric layer 26 may also be referred to as the field dielectric or FOX. The dielectric layer 26 may comprise an oxide such as silicon oxide. The dielectric layer 26 may comprise two or more sublayers, e.g. two sublayers formed of silicon oxide. The two sublayers may be formed by deposition or a first sublayer may be thermally grown and formed by oxidation of the surface of semiconductor substrate 12 and a second deposited sublayer may be deposited on the underlying thermally grown first sublayer.

The thickness of the dielectric layer 26 varies depending on whether the section of the trench structure 13 on which it is located is positioned in the edge region 19 or in the active area 18 of the semiconductor substrate 12. For the active portion 21 of the longitudinal trench section 16 which is located in the active area 18, the dielectric layer 26 has a thickness t_{act} on the sidewall 15. In some embodiments, the dielectric layer 26 located on the base 14 of the active portion 21 of the longitudinal trench section 16 which is located in the active region 18 also has the thickness t_{act}. The dielectric layer 26 located on the side wall 15 of the end portion 20 of the longitudinal trench section 16 which is located in the edge region 19 has a thickness t_{end}. The dielectric layer 26 located on the base 14 of the end portion 20 of the longitudinal trench section 16 which is located in the edge region 19 may also have the thickness t_{end}. The thickness t_{end} is greater than the thickness t_{act}. In some embodiments, the dielectric layer 26 located on the side wall 15 of the transverse trench section 17 also has the thickness t_{end}. In some embodiments, the dielectric layer 26 located on the base 14 of the transverse trench section 17 also has the thickness t_{end}.

In some embodiments, the thickness t_{end} is 5% between 5% and 25% greater than the thickness t_{act} i.e. 105% t_{act}≤t_{end}≤125% t_{act}. The thicknesses t_{end} and t_{act} are measured at a distance dₘ from the base 14 of the trench structure 13, the distance dₘ being ⅓ of the depth d of the trench structure 13. This enables a consistent comparison of the thickness. The depth d of the trench structure 13 is the distance between the base 14 of the trench 13 and the first major surface 11 of the semiconductor substrate 12.

In an embodiment, 110% t_{act}≤t_{end}≤120% t_{act}. The difference between the thickness of the dielectric layer 26 in the end region 19 and in the active area 18, (t_{end} t_{act}), may lie in the range of 5 nm≤(t_{end}−t_{act})≤40 nm, or 10 nm≤(t_{end}−t_{act})≤15 nm.

As can be seen in the top view of FIG. 1A, the side wall 15 of the trench structure 13 has a number of side wall sections. The longitudinal trench sections 16 are defined by two opposing side wall sections 15′, 15″ which extend parallel to one another to define the length of that longitudinal trench section 16. These two opposing side wall sections 15′, 15″ extend in opposing directions into one of the two side wall section 15′″, 15″″ of the transverse trench section 17. The angle between the side wall sections 15′, 15″ of the longitudinal trench section 16 and the side wall sections 15′″ of the transverse trench section 17 may be substantially 90°. Thus, a trench structure 13 is formed with an integral transverse trench section 17 and integral longitudinal trench sections 16 which extends substantially perpendicularly to the side wall 15′″ of the transverse trench section 17. Thus, a T-shaped trench arrangement is formed.

In the embodiments described herein, the longitudinal trench section 16 extends from one sidewall 15′″ of the transverse trench 17 and this sidewall 15′″ faces towards the active area 18. The opposing sidewall 15″″ of the transverse trench 17 faces outwardly towards the edge of the semiconductor substrate 12.

The transverse section 17 is integral with a plurality of longitudinal trench sections 16 such that the field plate section 25 in the transverse trench section 17 is integral with and electrically connects the parallel extending longitudinal sections 24 of the field plate 22 to one another at the end of the longitudinal trench sections 16. The field plate 22 also has a T-shape in top view.

As can be seen in the top view of FIG. 1A, and the cross-sectional views of FIGS. 1B and 1E, a mesa 27 is formed between the opposing sidewall sections 15′, 15′″ of two of the neighbouring longitudinal trench sections 16. The mesa 27 has an elongate stripe structure and an end face 30 which is bounded by the sidewall section 15′″ of the transverse trench section 17. The end portion 28 of the mesa 27 that is located in the edge region 19 is bounded on all three sides by the transverse trench section 17 and the two longitudinal trench sections 16. The mesa 27 is a so-called T-mesa termination mesa 27.

The mesa 27 has an end portion 28 which is located in the edge region 19 and an active portion 29 which is located in the active area 18. The end portion 28 of the mesa 27 that is located in the edge region 19 is bounded on all three sides by the dielectric material 26 having the greater thickness t_{end}. In contrast, the portion of the side wall sections 15′, 15″ of the longitudinal trench sections 16, which define the width of the mesa 27 and are located in the active area 18, are covered with dielectric layer 26 having the smaller thickness t_{act}.

FIG. 1B illustrates a cross-sectional view along the line A-A shown in figure 1A and a cross-sectional view of the end portion 20 of the two longitudinal trench sections 16 that are located in the edge region 19 of the semiconductor substrate 12. FIG. 1B illustrates that the dielectric layer 26 has the thickness t_{end} on the sidewall 15 and base 14.

FIG. 1C illustrates a cross-sectional view along the line B-B shown in FIG. 1A and shows a cross-sectional view of the transverse trench section 17 and a cross-sectional view along the length of the integral longitudinal trench section 16. FIG. 1C illustrates that the transverse field plate section 25 is bounded at its side face by a dielectric layer 26 having the larger thickness t_{end} and shows that the thickness of the dielectric layer 26 decreases to the smaller thickness t_{act} at a position of the longitudinal trench section located at the boundary, indicated with dashed line 23, between the edge region 19 and the active area 18 of the semiconductor substrate 12.

FIG. 1D illustrates a cross-sectional view along line C-C shown in FIG. 1A and illustrates a cross-sectional view of the transverse trench section 17 and the mesa 27. In this embodiment, it can be seen that the dielectric layer 26 which bounds the end face 30 of the mesa 27 has the thickness t_{end}.

FIG. 1E illustrates a cross-sectional view along line D-D shown in FIG. 1A and illustrates a cross-sectional view of two longitudinal trench sections 16 in a plane that is located in the active area 18. In this plane of the longitudinal trench section 16, the dielectric layer 26 on the sidewalls 15 and base 14 of the longitudinal trench sections 16 has the smaller thickness t_{act}.

In some embodiments, the semiconductor device 10 comprises a transistor device. The transistor device may further include a non-illustrated gate electrode which may be located in a gate trench formed in the mesa 27 or may be a lateral gate formed on the upper surface of the mesas 27. In another embodiment, the gate electrode is located in the trench structure 13 above the field plate 22 and has the same lateral form as the field plate 22. The semiconductor substrate 12 has a first conductivity type, for example type.

As shown in the cross-sectional view of the active area 18 of FIG. 1E, the transistor device further includes a body region 31 of second conductivity type which opposes the first conductivity type of the semiconductor substrate 12. The body region 31 is located in the active area 18 and, optionally, the body region 31 further extends into at least part of the edge region 19. The transistor device further includes a source region 32 of the first conductivity type which is located on and/or in the body region 31. The source region 32 is, however, located only in the active area 18 so that the edge region 19 is free of the source region, see FIG. 1D which shows the end portion 28 of the mesa 27 which is located in the edge region 19. A drain region may be located on the second major surface of the semiconductor substrate 12 which opposes the first major surface 11. The drain region and second major surface of the semiconductor substrate are not illustrated in FIGS. 1A-1E.

In some embodiments, the gate electrode may be located in the trench structure 13 above the field plate 27. In these embodiments, the gate electrode is electrically insulated from the field plate 22 and from the semiconductor substrate 12 by the dielectric layer 26, an intermediate dielectric layer located between the field plate 22 and the gate electrode and a gate dielectric located on the side wall 15.

The structure of the transverse trench 17 at the outwardly facing sidewall section 15″″ may differ from that of the opposing inwardly facing sidewall section 15′″. For ease of processing, the dielectric layer 26 located on the outwardly facing sidewall 15″″ of the transverse trench structure 17 may have the increased thickness t_{end}, but could have the thickness than smaller thickness t_{act}, since the outwardly facing sidewall 15″″ does not bound the mesa 27.

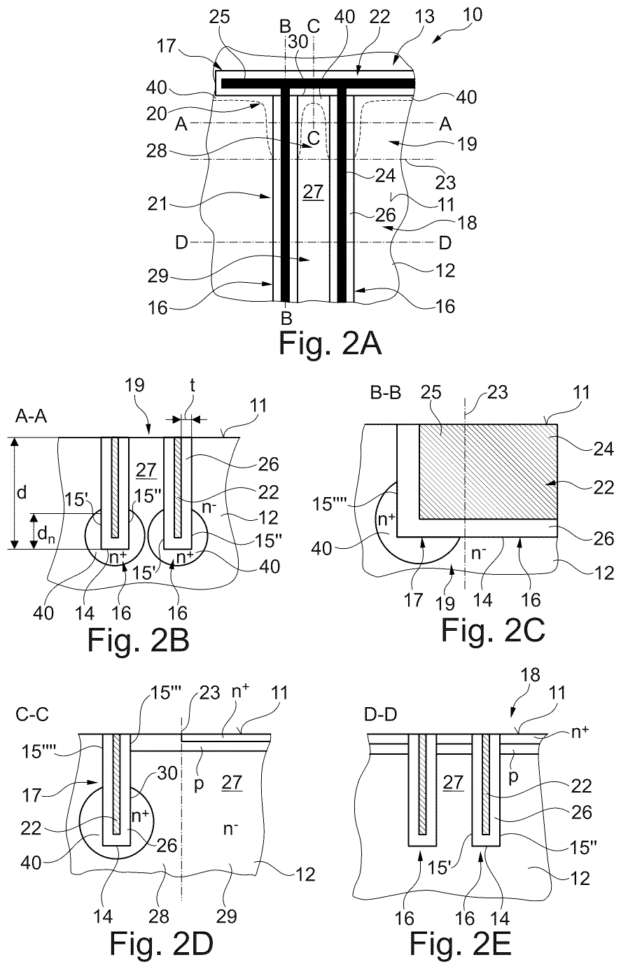

FIGS. 2A to 2E illustrate views of a semiconductor device 10 according to another embodiment. FIG. 2A illustrates a plan view, FIG. 2B illustrates a cross-sectional view along the line A-A shown in FIG. 2A, FIG. 2C illustrates a cross-sectional view along the line B-B shown in FIG. 2A, FIG. 2D illustrates a cross-sectional view along the line C-C shown in FIG. 2A and FIG. 2E illustrates a cross-sectional view along the line D-D shown in FIG. 2A.

As in the in the embodiment illustrated in FIGS. 1A to 1E, the semiconductor device 10 comprises a trench structure 13 formed in the first major surface 11 of the semiconductor substrate 12. The trench structure 13 includes a transverse section 17 in the edge region 19 and a plurality of longitudinal trench section 16 extending from one side of the transverse section 17 from the edge region 19 into the active area 18. The field plate 22 is located in the trench structure 13 and has a transverse section 25 and longitudinal sections 24 extending from and integral with the transverse section 25 as in the embodiment illustrated in FIGS. 1A to 1E. The dielectric layer 26 is located on the sidewall 15 and base 14 of the trench structure 13 and electrically insulates the field plate 22 from the semiconductor substrate 12. In this embodiment, the dielectric layer 26 has a thickness t which is substantially uniform over the active area 18 and edge region 19 on the side walls 15 and base 14 of the trench structure 13.

FIG. 2A illustrates a schematic top view of a portion of the first major surface 11 of the semiconductor device 10. FIG. 2B a schematic cross-sectional view along the line A-A of FIG. 2A and illustrates a cross-sectional view of the two longitudinal trench sections 16 in a plane located in the edge region 19.

The semiconductor substrate 12 has a first conductivity type and a doping level X of the dopants of the first conductivity type of in the active region. X may lie in the range of ×10¹⁶·cm⁻³ to 2×10¹⁷ cm⁻³. Referring to FIGS. 2A and 2B, in this embodiment, the semiconductor substrate 12 further comprises a doped region 40 of the first conductivity type which has a doping level Y which is greater than the doping level X of the semiconductor substrate in the active region. The further regions of the edge region 19 which are outside of the doped region 40 also have the doping level X. The doped region 40 and the semiconductor substrate 12 have the same doping type and the doped region 40 is distinguishable from the semiconductor substrate 12 in the concentration of the dopants of the first conductivity type. The doped region 40 of the first conductivity type that has the doping level Y which lies in the range of 1×10¹⁶ cm⁻³ to 2×10¹⁷ cm⁻³ and is between 15% and 35% greater than the doping level X, so that 115% X≤Y≤135% X. In an embodiment, the first conductivity type is n-type and the semiconductor substrate 12 is formed of silicon and the dopants are phosphorous.

As can be seen in the cross-sectional view of FIG. 2B, the doped region 40 is located adjacent the end portion 20 of the longitudinal trench sections 16 which is located in the edge region 19. The doped region 40 is located adjacent the lower half of the end portion 20 of the longitudinal trench section 16. In other words, the doped region 40 is located at least a distance dₙ from the first major surface 11 which is greater than half of the depth d of the trench structure 13. In some embodiments, the doped region 40 is located in the semiconductor substrate 12 under the base 14 of the end portions 20 of the longitudinal trench sections 16. In some embodiments, the doped region 40 is located in the end portion 28 of the mesa 27 adjacent the sidewall 15 of the end portion 20 of the longitudinal trench section 16. In some embodiments, the doped region 40 is located in the semiconductor substrate 12 under the base 14 and adjacent the sidewall 15 of the end portion 20 of the longitudinal trench structure 16. In some embodiments, the surface of the semiconductor substrate 12 which forms the base 14 and lower portion of the sidewalls 15 of the longitudinal trench sections 16 is formed of semiconductor material having the higher doping level Y.

The doped region 40 comprising the higher doping level Y is located exclusively in the end region 19 so that in the active are 18, the semiconductor substrate 12 and the active portion 29 of the mesa 27 has the lower doping level X.

FIG. 2C illustrates a cross-sectional view along the line B-B of FIG. 2A and illustrates a cross-sectional view of the transverse trench section 17 where it transitions into the longitudinal trench section 16. FIG. 2D illustrates a cross-sectional view of the transverse trench 17 along the line C-C.

Referring to FIGS. 2C and 2D, can be seen that the doped region 40 also extends into the semiconductor substate 12 under the base 14 and adjacent the side wall 15′″ of the transverse trench section 17 that is located between the two neighbouring longitudinal trench sections 16 and that forms the end face 30 of the mesa 27. The end portion 28 of the mesa 27 located in the edge region 19 is, therefore, bounded on three sides by the doped region 40, as can also be seen in the top view of FIG. 2A. The mesa 27 has one or more doped regions 40 in the lower half of the height of the mesa 27 that are located at its sidewall sections 15′, 15″ and end face 30 which surround the end portion of the mesa 27. In some embodiments, the doped region 40 may be located in the mesa 27 adjacent the three adjoining faces terminating the mesa 27, i.e. the end face 30 and opposing side wall sections 15′, 15″ of the two adjacent longitudinal trench sections 16 which define the width of the mesa 27.

FIG. 2E illustrates a cross-sectional view along line D-D and shows a cross-sectional view of the longitudinal trench section 16 in a plane which is located in the active region 18. Referring to FIG. 2E, it can be seen that no doped region is formed at the base 14 or side wall 15 of the active portions 21 of the longitudinal trench sections 16 which are located in the active region. The doping level X of the active portion 29 of the mesa 27 that is located in the active region 18 of the semiconductor substrate 12 is substantially uniform.

Referring to FIGS. 2A to 2D, in an embodiment, the doped region 40 is located under the base of the end portion of the plurality of longitudinal trench sections 16 that is located in the edge region 19 and has a doping concentration Y, wherein 115% X≤Y≤135% X. The doped region 40 may located adjacent a lower half of the side wall sections 15′, 15″ of the end portion 20 of the plurality of longitudinal trench sections 16 that are located in the edge region 19, wherein 115% X≤Y≤135% X. The doped region 40 may located adjacent a lower half of the side wall sections 15′, 15″ of the end portion 20 and under the base 14 of den the plurality of longitudinal trench sections 16 that are located in the edge region 19, wherein 115% X≤Y≤135% X.

In some embodiments, 120% S≤Y≤125% X.

The semiconductor substrate 12 may be formed of an epitaxial layer, e.g. an epitaxial silicon layer hat has the doping level X of 1×10¹⁶·cm⁻³ to 2×10¹⁷ cm⁻³. The epitaxial layer may be located on a base substrate. The base substrate may be formed of silicon and have the first conductivity type. The base layer may have a higher doping level than the doped region. The base substrate or a highly doped portion of the base substrate may provide the drain region of the transistor device.

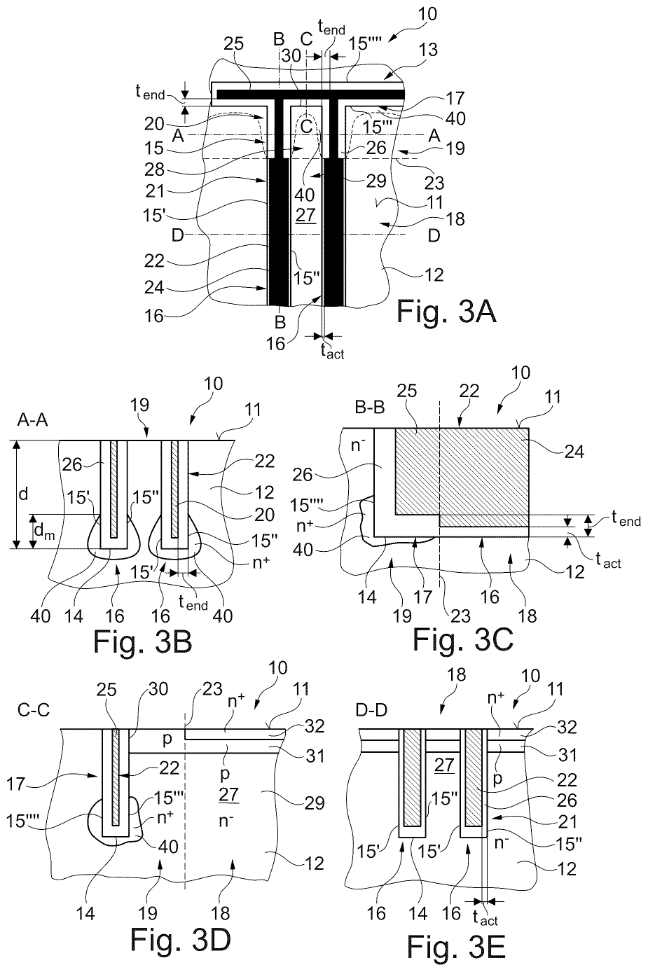

FIGS. 3A to 3E illustrate various views of a semiconductor device 10 a combination of the more highly doped region 40 in the edge portion 28 of the mesa 27 and the areally varying thickness of the dielectric layer 26. In this embodiment, the semiconductor device 10 includes a combination of the dielectric layer 26 with its increased thicknesses in the edge region 19, t_{end}, and smaller thickness in the active area 18, t_{act}, as described with reference to FIGS. 1A-1E and the doped region 40 with the doping level Y that is higher than the doping level X of the semiconductor substrate 12, as described with reference to FIGS. 2A to 2E.

FIG. 3A illustrates a top view of the semiconductor device 10, FIG. 3B illustrates a cross-sectional view along the line A-A shown in FIG. 3A, FIG. 3C illustrates a cross-sectional view along the line B-B shown in FIG. 3A, FIG. 3D illustrates a cross-sectional view along the line C-C shown in FIG. 3A and FIG. 3E illustrates a cross-sectional view along the line D-D shown in FIG. 3A.

FIGS. 3A to 3E show that the end portion 20 of the longitudinal trench sections 16 and the transverse trench section 17 comprise a dielectric layer 26 having the thickness t_{end} which is greater than the thickness t_{act} of the dielectric layer 26 in the active region 18 and comprise a more highly doped region 40 that is located in the mesa 27. The doped region 40 is located in the end portion 28 of the mesa 27 located in the edge region 19 and adjacent the end face 30 in the lower portion of the mesa 17, for example adjacent the base 14 of the longitudinal trench section 16 or adjacent the facing sidewall sections 15′, 15″ of the two longitudinal trench sections 16 which define the width of the mesa 27. The doped region 40 may be located at a position in the mesa 27 which is less than half of the depth, d, of the longitudinal trench sections 16, the depth of the longitudinal trench sections 16 corresponding to the height of the mesa 27.

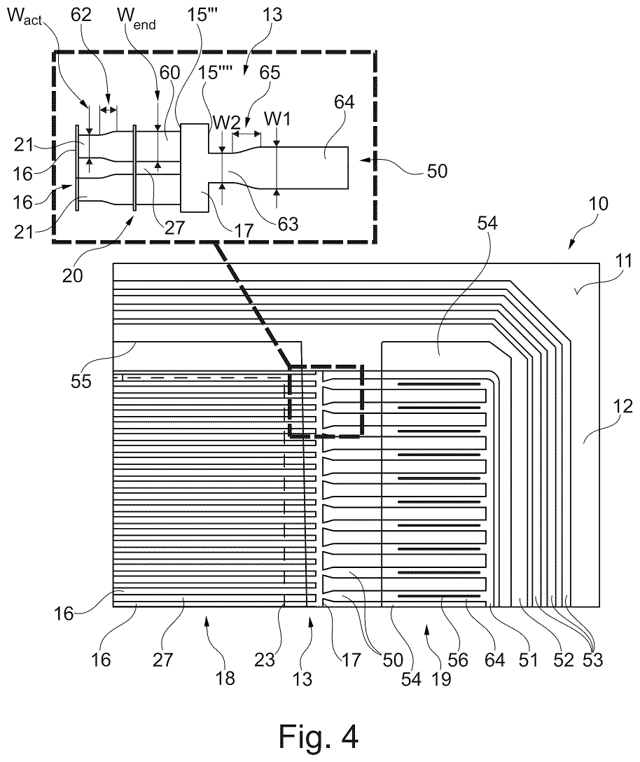

FIG. 4 illustrates a top view of a semiconductor device 10 according to an embodiment and illustrates a schematic representation of the T design at the trench termination.

FIG. 4 illustrates a corner region of the semiconductor substrate 12 and shows a portion of the active region 18 and the edge region 19 of the semiconductor device 10. The semiconductor device 10 includes a trench structure 13 with a plurality of longitudinal trench sections 16 which extend parallel to one another and perpendicularly from an inwardly facing sidewall 15′″ of the transverse trench structure 17. The longitudinal trench sections 16 each have an end portion 20 that is arranged in the edge region 19, which is free of source region, and extend into the active area 18. The longitudinal trench sections 16 may extend throughout the active area 18 and into the edge region 19 on the opposing side of active area 18.

FIG. 4 also illustrates further structures located in the edge region 19 which include a further plurality of further longitudinal trench sections 50 which extend from the outwardly facing sidewall 15″″ of the transverse trench section 17, substantially perpendicularly to this sidewall 15″″ and substantially parallel to the longitudinal trench sections 16. The spacing between the further longitudinal trench sections 50 is larger than the spacing between longitudinal trench sections 16. The further longitudinal trench sections 50 in the edge region 19 have a greater width than the longitudinal trench sections 16 which extend into the active area 16. The field plate 22 extends from the transverse trench section 17 into these further longitudinal sections 50.

The further longitudinal sections 50 are connected by a second transverse trench 51 at the opposing end of the length of the further longitudinal trench sections 50 to the transverse trench section 17. The edge region 19 further comprises at least one continuous ring-shaped trench 52 which is outboard of the transverse trench section 17 and which laterally and uninterruptedly surrounds the active region 18 end transverse trench 51, the further longitudinal trench sections 50 and the active area 18. The ring-shaped trench 52 is filled with polysilicon. The edge region 19 further comprises one or more further continuous trenches 53 which are located outboard of the ring-shaped trench 52. The one or more further continuous trenches 53 are also ring-shaped and laterally surround the trench 52. The further continuous trenches 53 may be filled with insulating material, e.g. an oxide such as silicon oxide.

The field plate 22 is electrically connected to source potential by a metallization layer 54 which extends over the peripheral end portions of the further longitudinal trenches 50 and at least partially over the polysilicon material in the ring-shaped trench 52. A contact via 56 extends between the portion of the field plate 22 that is located in the further longitudinal trench section 50 and the overlying metallization layer 54 to electrically connect the field plate 22 to the electrically conductive polysilicon material in the ring-shaped trench 52.

Also shown in FIG. 4 is the position of a second longitudinal second metallization structure 55 which is electrically connected to the source region 32 and the polysilicon in the trench 52 so as to electrically connect the field plate 22 by way of the conductive vias 56, metallization layer 54, polysilicon 52 and metallization structure 55 to the source region 32 and source potential.

FIG. 4 also includes an enlarged view of the transition between two of the longitudinal trench sections 16 and the transverse trench 17 and one of the further longitudinal sections 50. The further longitudinal transection 50 is aligned with the mesa 27 and is arranged laterally between the longitudinal trench sections 16.

In the embodiment illustrated in FIG. 4, the longitudinal trench sections 16 have a peripheral end portion 60 which transitions into the transverse trench section 17. The peripheral end portion 60 has a width, W_{end}, which is greater than the width W_{act} of the portion 61 of the longitudinal trench section 16 that is located in the active area 18 of the device 10. The transition 62 between the end portion 60 with the greater width W_{end} and the smaller width W_{act}. of the active portion 21 of the longitudinal trench sections 16 is located in the edge region 19.

The further longitudinal transection 50 has a proximal end portion 63 which adjoins the outwardly facing side wall 15″″ of the transverse trench section 17 which has a smaller width, W1, than the width, W2, of the remainder 64 of the longitudinal trench section 50, for example the portion that is located under the conductive via 56. A smooth transition 65 is provided between the proximal end portion 63 and the remainer 64 of the further longitudinal trench section 50.

The so-called T-termination mesa 27, which is bounded at its end face 30 by the transverse trench 17 that transitions into the longitudinal trench sections 16 defining the width of the mesa 17. The so-called T-mesa termination 27 has been widely used in various transistor technologies and while there are benefits of using such mesa terminations with respect to design ruggedness, it has also its challenges, such as that the difference in compensation (3D) compared to the active area of the cell, may create a breakdown voltage dependance on the current density.

For low currents, the breakdown voltage (BV) of the device may be limited by the termination. The actual breakdown of the cell may be hindered and may be only shown at high currents or by a stress mechanism that can shift the breakdown from the termination to the active cell. This may create a weakness in the device ruggedness limited by the T mesa termination and may have an impact on the device reliability, for example Vds overshoot in application exceeds the breakdown voltage of the device in a cell designed with too low BV,—device goes in avalanche causing shift of electrical parameters like Rdson etc. Furthermore, the fact that the BV in the device, e.g. transistor device, depends on the termination, may limit the modeling and assessments of statistics derived from simulations and data analysis based on TCAD models.

In the technologies where T mesa termination is used in the design, the BV limitation by the termination may, for example, be addressed, by either overengineering of the cell to compensate for the termination—leading to impact on other electrical parameters that worsen the performance of the device, for example epi engineering with penalty on Rdson etc. or by engineering of testing conditions (whenever possible) to move the BV to the cell field without compromise on device reliability or testing costs.

According to the present disclosure, engineering the compensation in the T-mesa termination is performed via implants to form the more highly doped region 40 or a field dielectric 26 thickness increase in the edge region 19. This may improve the weakness of the termination and allow for an increase in BV of the termination, closer to the real cell breakdown. By engineering the termination with the proposed methods in this disclosure (such as thicker FOX in the edge termination and/or implanting dopants of the same type as the dopants of the semiconductor substrate, e.g. n-type, into at least one of under the trench and beside the sidewall of the trench), the BV of the termination can be improved with no or only little influence on the active transistor cells of the transistor device.

As explained earlier, the proposed mesa termination relates to managing the electric field distribution at the edge of the active area as the shape can influence the breakdown voltage of the device. In this specific shape, the compensation from three sides and a narrower mesa can lead to potential lines being squeezed between substrate and trench bottom.

A different approach proposed in this disclosure in order to relax the above-mentioned squeezing of the lines of potential in the mesa, is to create higher mesa doping at the mesa ending. This can be achieved by the n+ phosphorous implantation at the termination region for n-type semiconductor substrates. In a typical process flow, there are two stages when this additional implantation can be implemented. After the hard mask opening or after the trench etch. Both approaches aim to increase the concentration of phosphorous along the trench in the termination area by, for example, approximately 25%.

Referring to FIGS. 2A-2E and 3A-3E, the location of the doped region 40 within the semiconductor substrate 12 and its doping concentration may be selected by selecting the angle of implantation or tilt and the dose of the implanted dopants, e.g. phosphorus ions.

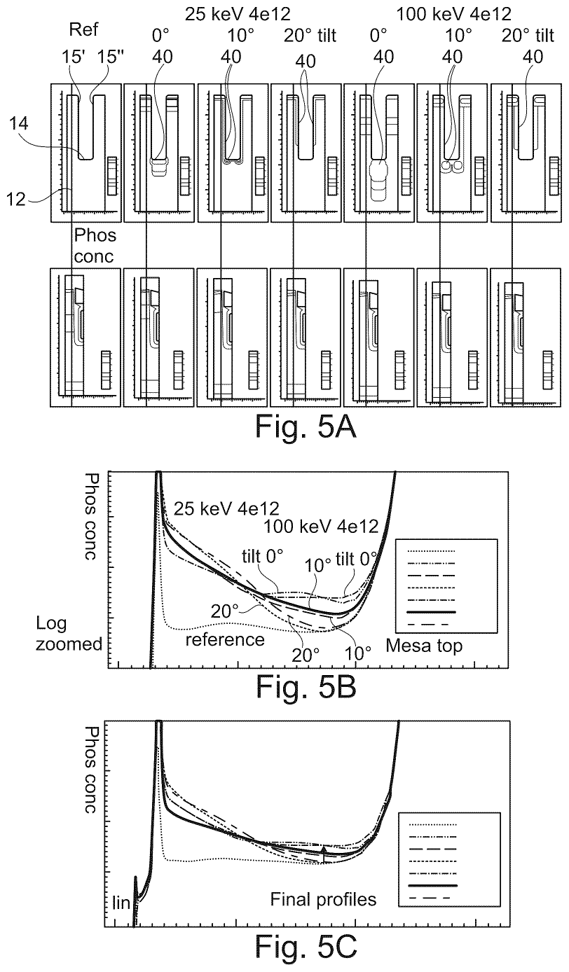

FIG. 5A shows exemplarily implant simulation results which depicts the dopant concentration, e.g. n-type dopant concentration such as phosphorous concentration, at trench and mesa area for different tilts or 0°, 10° and 20° to the first major surface 11 and two doses 25 keV, 4e¹² and 100 keV and 4e¹². FIGS. 5B and 5C show phosphorous concentration profiles zooming at the mesa top and final phosphorous concentration profiles for different tilt and dose in comparison to the reference (black line).

Using these simulations, the appropriate n+ implantations needed to achieve the desired effect at the mesa regions can be estimated. Compared to the reference example, the implanted examples have a phosphorous concentration which increases with increasing depth. With implantations taking place after the trench etch and 0° tilt, a phosphorous implantation at the mesa and trench bottom is achieved. In addition to this, as seen in FIGS. 2A-2E, the use of 100 keV results in a better depth distribution than 25 keV. With a tilt of 20°, a higher phosphorous concentration at mesa top is achieved. At a tilt of 30°, an increased phosphorous concentration is not produced at the bottom of the trench and mesa.

In an example, a refence wafer has a Vbd at 30.5V. The results of the implantation (n+ phosphorous implantation at the termination region discussed above) can improve the Vbd by about 1V. The improvement achieved by the thicker FOX in the edge termination can be seen achieving increasing the Vbd by almost 2.5V. In both cases the value of Rdson at Vgs=4.5 V did not increase in comparison to the reference. Finally, the Vbd achieved when increasing the epi thickness by 0.27 μm leads to an increase of 1.5V but the value of Rdson at Vgs=4.5V is also increased by 7.5% in comparison to the reference.

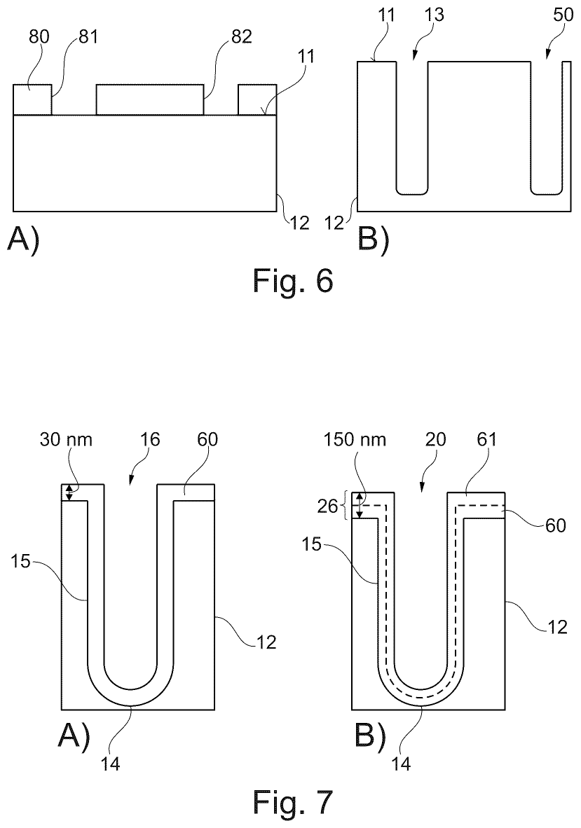

A method for forming the doped region 40 in the edge region will be described with reference to FIG. 6. Schematic cross section (A) of FIG. 6 shows the termination during the implantation according to an embodiment, in which implantation is performed at hard mask opening. Schematic cross section (B) of FIG. 6 shows the termination during the implantation, according to an alternative embodiment, in which implantation is performed into the trench structure after trench etch.

Referring to schematic cross section (A) of FIG. 6, in an example, a hard mask 80 is formed on the first major surface 11 of the semiconductor substrate. The hard mask 80 has openings 81, 82 corresponding to the position of the trench structure 13 including the transverse trench structure 17 which is located in the edge region 19 and the longitudinal trench structures 16 which extend from the transverse trench structure 17 into the active area 18. The hard mask 80 may be formed of silicon oxide or silicon nitride, for example. The hard mask 80 is then used to from the trench structure 13 by etching so that the regions of the substrate 12 that are exposed by the opening are etched and removed, as shown in schematic cross section (B) of FIG. 6. In an embodiment, the termination implant to form the doped region 40 is performed after hard mask (HM) 80 is structured to form the openings 81, 82.

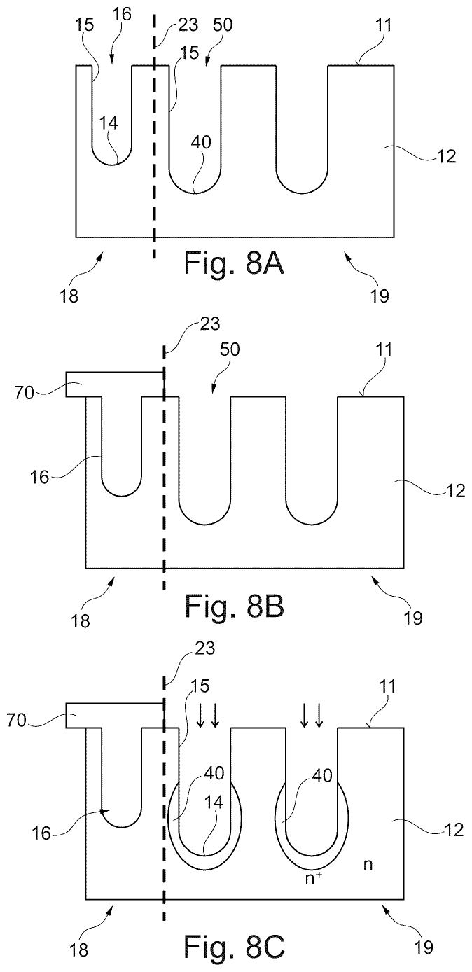

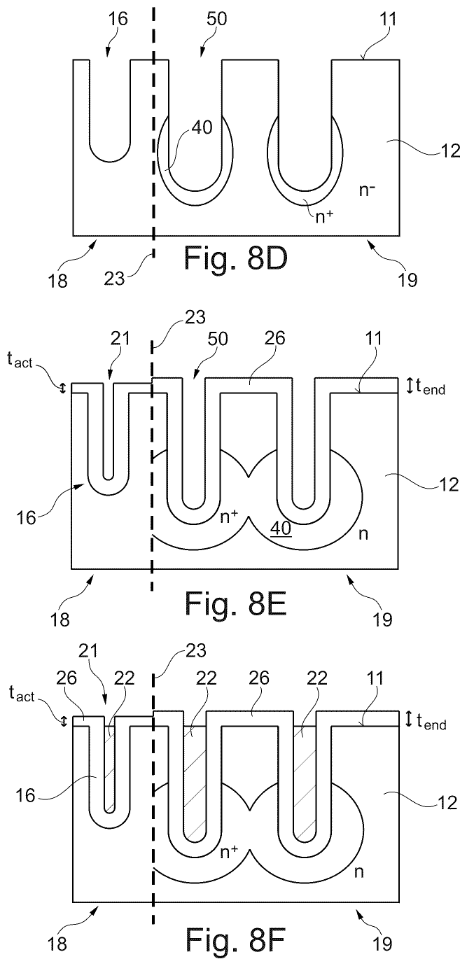

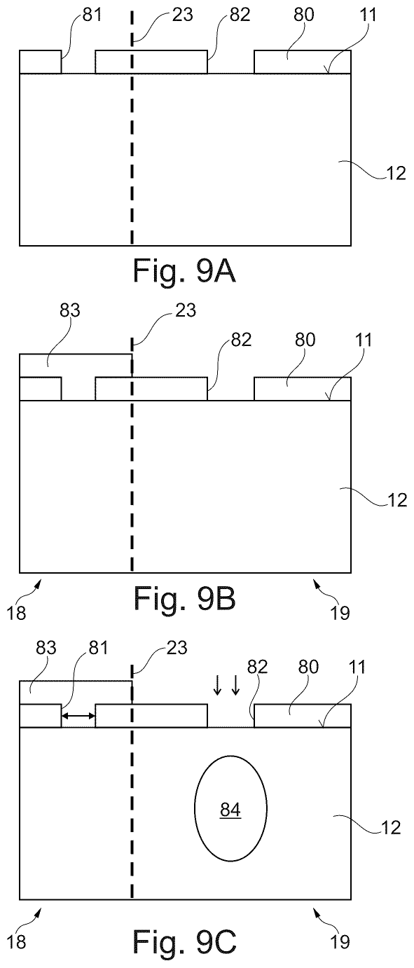

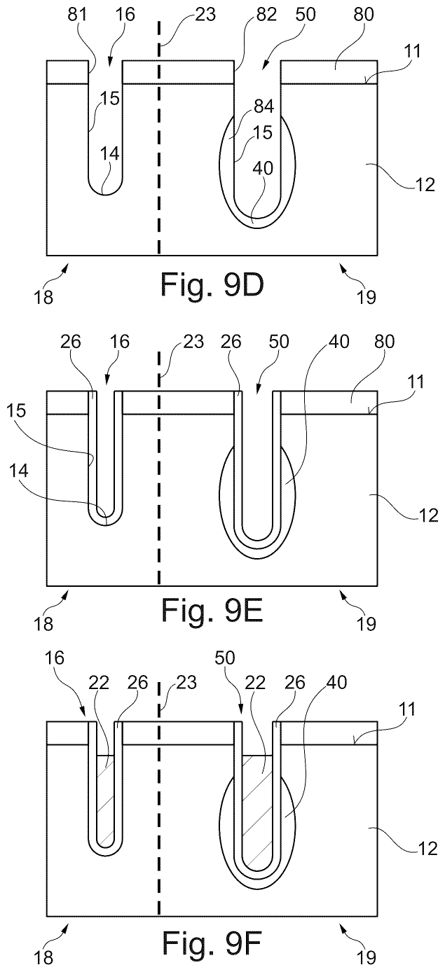

Alternatively, and referring to schematic cross section (B) of FIG. 6, the termination implant to form the doped region 40 is performed after trench etch using a lithography step that allows for additional n+ implantation in the termination area. A reticle is used either after hard mask opening (schematic cross section (A) of FIG. 6 and FIG. 9A-9F) or after trench etch (schematic cross section (B) of FIG. 6 and FIG. 8A-8F) to enable the implantation in the termination region only. Hence, the active area is protected by the hard mask 80 from the additional implantation.

In some embodiments, for example as illustrated in and described with reference to FIGS. 1A-1E and 3A-3E, The dielectric layer 26 has the greater thickness, t_{end}, in the end portions 20 of the longitudinal trench section 16 and transverse trench section 17 located in the edge region 19 and the smaller thickness, t_{act}, in the active portions of the longitudinal trench sections 16 that are located in the active area 18. This areal different in the thickness of the dielectric layer 26 of the semiconductor device 10 may be fabricated using various methods.

According to an example, the development of the FOX is done via a 3-step approach. First, the growth of a thermal oxide (e.g., 10-40 nm, such as 30 nm). Second, a wet clean step that removes partially (such as 5-15 nm, e.g., approximately 10 nm) and the TEOS deposition leading finally to a thick Field Oxide (such as 100 nm-250 nm, e.g., 150 nm). The thicker FOX at termination is achieved by an additional lithography step after the growth of the thermal FOX. At this step an additional reticle is blocking the wet etch at the termination only leading eventually to a thicker FOX compared to the cell field.

In another example, the dielectric layer 26, e.g. silicon oxide, is formed in the edge region 19 including the end portions 20 of the longitudinal trench sections 16 that are located in the edge region 19 and in the transverse trench section 17. This dielectric layer 26 has a final thickness, which is desired in these edge regions, i.e. the thickness t_{end}. Then, portions of the dielectric layer 26 are removed from at least the side walls 15 of the longitudinal trench sections 16 located in the active area 18 and its thickness is reduced to the desired thickness required for the active cell, i.e. t_{act}. This method may be used creating larger thickness differences between the thicknesses t_{end} and t_{act}.

Schematic cross section (A) of FIG. 7 shows the termination, e.g. the end portion of the longitudinal trench section, after thermal growth of a first sublayer of the dielectric layer. Schematic cross section (B) of FIG. 7 shows the termination, e.g. the end portion of the longitudinal trench section, after the fabrication of a thicker dielectric layer.

The thicker the dielectric layer 26, which serves as FOX, in the termination, the higher the BV improvement. This is due to the fact that thicker FOX impacts the compensation at the termination region and the BV in the termination is improved. The reason we cannot increase the FOX thickness both in the active cell and the termination, is because with this pitch, the material of the field plate (“poly S” refers to electrically conductive polysilicon) will become narrower leading to a high Poly S resistance (RXSpoly). This is an unwanted effect that can degrade the reliability of the device. Hence, the proposed lithography step may increase the Vbd. At the same time a penalty on the RXSpoly resistance may be decreased.

Schematic cross section (A) of FIG. 7 shows a schematic cross section of the termination, e.g. the end portion 21 of the longitudinal trench section 16, after thermal growth of a first sublayer 60 of the dielectric layer 26. Schematic cross section (B) of FIG. 7 shows a schematic cross section of the termination, e.g. the end portion 21 of the longitudinal trench section 16, after the fabrication of a thicker dielectric layer. For example, the thicker dielectric layer may have a thickness of 150 nm.

In some examples, the first sublayer 60 is thermally grown FOX, as shown in schematic cross section (A) of FIG. 7, and has a thickness of around 30 nm. A second sublayer 61 is formed on the first sublayer 60 in the edge region 19 only, for example by deposition of silicon oxide, so as to increase the total thickness of the dielectric layer 26.

With the introduction of the lithography step, a difference between the thicknesses t_{end} and t_{act} of up to 20 nm can be reached by varying the duration of the wet etch part, which is sued to reduce the thickness of the dielectric layer located in the active area 18, for example to reduce the thickness from 150 nm to 130 nm or less in the active area 18. To engineer an even thicker FOX at the termination, a thicker thermal FOX is grown and a higher duration of a wet etch can be applied. Oxide growth may lead to 50% silicon consumption. Therefore, a thicker FOX will consume more Silicon and this should be counterbalanced by an adaptation in the top critical dimensions (CD) of the trench. This is an alternative implementation that has also been achieved leading to a higher degree of Vbd improvement maintaining at the same time a low RXSpoly.

In some embodiments, an additional doped region 40 comprising dopants of the same conductivity type as the semiconductor substrate 12 is formed in the end portions of the longitudinal trench sections 16 which are located in the edge region 19 and in the transverse trench sections 17. If, for example, the first conductivity type is n type, the doped region may be described n+ and the semiconductor substrate as in n−. The semiconductor substrate 12 may provide the drift region of a transistor device structure, for example. The mesa 27 in regions outside of the doped region may have a doping level of X. The doped region may have a doping level of Y, wherein 115% X≤Y≤135% X.

FIGS. 8A-8F show a process flow of how an increased doping concentration of the first dopants, e.g. n+ concentration, can be achieved at the bottom and sidewalls of a trench in one embodiment (e.g., after trench etch).

FIGS. 8A-8F show respective cross-sectional views of the transverse trench section 17 and the end portion 20 of the longitudinal trench section 16 in the edge region 19 and a cross-sectional view of an active portion 21 portion of the longitudinal trench section 16 which is located in the active area 18. Referring to FIG. 8A, the transverse trench section 17 as well as the longitudinal trench sections 16 which extend from the transverse trench section 17 into the active area 18 are formed. In some embodiments, the edge trenches 50 have different dimensions to the trench structure 13. For example, the edge trenches 50 may be wider and deeper than the trench structure 13, in particular, the longitudinal trench sections 16 which are located in the active area 18. The trench structure 13 may be formed by etching, for example wet etching.

Referring to FIG. 8B, the active area 18 may be covered with a mask 70, for example formed of photoresist. The edge region 19, including the end portions of the longitudinal trench sections 16 and transverse trench section 17 that are located in the edge region 19 are uncovered by the material of the mask 70. Dopants of the first conductivity type, which are the same as the conductivity type of the semiconductor substrate 12, are implanted into the base 14 and sidewalls 15 of the uncovered trenches, that is the uncovered end portions of the longitudinal trench sections 16 and the transverse trench section 17 as illustrated in FIG. 8C by the arrows to form the doped region 40 in the semiconductor substrate under the base 14 of the trench structure 13 and adjacent the lower portions of the side wall 15 of the trench structure 13. Then, the mask is removed, as shown in FIG. 8D, uncovering the active area 18 of the semiconductor device 10. Referring to FIG. 8E, subsequently, the dielectric layer 26 is formed, e.g. deposited, on the sidewall 15 and base 14 of the trench structure 13. During subsequent processes, the implanted dopants may defuse, thus increasing the volume of the doped region 40 and slightly decreasing the doping concentration of the doped region. In some embodiments, for example as illustrated in FIG. 3E, the dielectric layer 26 may have a smaller thickness in the active area 18 compared to the edge region 19. Any one of the embodiments described herein can be used to create this difference in the thickness of the dielectric layer 26.

Referring to FIG. 8F, conductive material is then inserted into the trench structure 13 to form the field plate 22 in the trench structure 13. In some embodiments, a gate electrode may then be formed in the trench structure 13 above the field plate 22. The body region 31 and the source region 32 may then be formed by implantation.

FIGS. 9A to 9F show a process flow of how a n+ concentration can be achieved at the bottom and sidewalls of a trench according to another embodiment (e.g., after hard mask opening or before trench etching).

FIG. 9A illustrates the semiconductor substrate 12 including a hard mask 80 on its first major surface 11. The hard mask 80 may be formed of silicon nitride, for example. The hard mask 80 has openings 81, 82 corresponding to the position of the trench structure 13 including the transverse trench structure 17 which is located in the edge region 19 and the longitudinal trench structures 16 which extend from the transverse trench structure 17 into the active area 18. A mask 83, for example a soft mask comprising photoresist, may then be applied which covers the openings 81 in the mask in the active area 18, as shown in FIG. 9B. The edge region 19 remains uncovered by the mask 80. Dopants of the same conductivity type as the semiconductor substrate, e.g. of the first conductivity type, e.g. n-type, may then be implanted through the opening 82 in the mask 80 and into the edge region 19 so as to form a buried doped region 84 in the edge region 19, as shown in FIG. 9C. The buried doped region 84 is spaced apart from the first major surface 11 and opposing second major surface by a region of the semiconductor substrate 12 which has a lower doping level.

Referring to FIG. 9D, the photoresist mask 83 is then removed from the active area 18 and the openings 81, 82 in the hard mask 80 are then used in an etching process to form the trench structure 13 and the semiconductor substrate 12. The transverse trench structure 17 and end portions of the longitudinal trench section 16 are located in the more highly doped region 84 such that the base 14 and lower portion of the sidewalls 15 of the trench structure 13 in these positions are formed by semiconductor material having a higher doping level than the doping level of the sidewall 15 in regions adjoining the first major surface 11. The hard mask 80 is then removed and the dielectric layer 26 formed on the sidewall 15 and base 14 of the trench structure 13, as shown in FIG. 9E. The dielectric layer 26 may have a uniform thickness throughout the active area 18 and edge region 19 or may have a greater thickness in the edge region 19 compared to the active area 18. The difference in the thickness of the dielectric layer 26 may be formed using any one of the methods described herein.

The implantation of the dopants of the first conductivity type may be carried out at a 0° tilt to the first major surface 11, in other words perpendicular to the first major surface 11, or up to an angle of 20° tilt to the first major surface 11. The tilt angle may be varied depending on the depth of the trench structure 13 and the height of the area into which the dopants should be implanted.

Referring to FIG. 9F, conductive material is then inserted into the trench structure 13 to form the field plate 22 in the trench structure 13. In some embodiments, a gate electrode may then be formed in the trench structure 13 above the field plate 22. The body region 31 and the source region 32 may then be formed by implantation.

In some embodiments, for example as illustrated in and described with reference to FIGS. 1A-1E and 3A-3E, The dielectric layer 26 has the greater thickness, t_{end}, in the end portions 20 of the longitudinal trench section 16 and transverse trench section 17 located in the edge region 19 and the smaller thickness, t_{act}, in the active portions of the longitudinal trench sections 16 that are located in the active area 18. This areal different in the thickness of the dielectric layer 26 of the semiconductor device 10 may be fabricated using various methods.

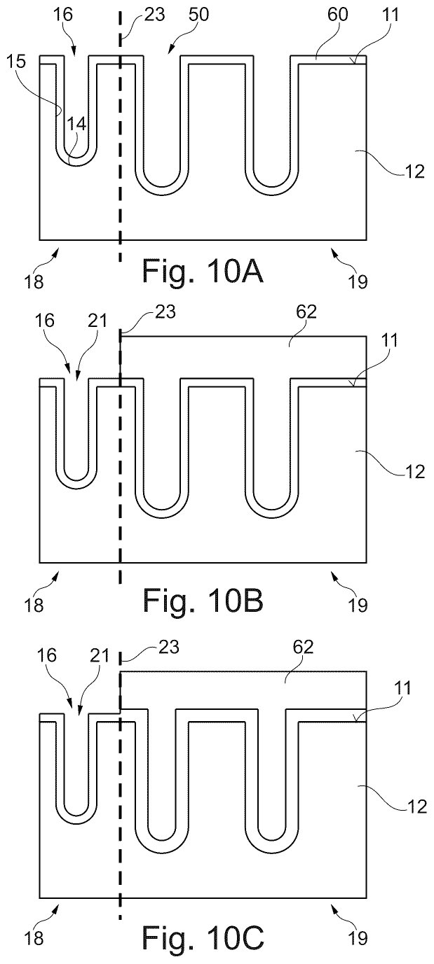

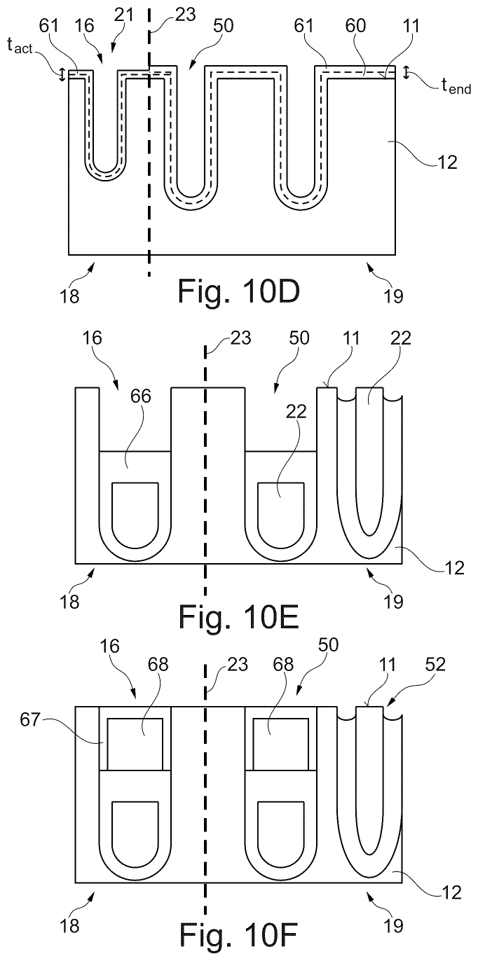

FIGS. 10A to 10F describe an embodiment in which the dielectric layer 26 is formed by forming two sublayers. FIGS. 10A-10F illustrate a portion of the active area 18 and an active portion 21 of one of the longitudinal trench sections 16 on the left and a portion of the edge region and the transverse trench on the right.

A first sublayer 60 is formed on the base 14 and sidewall of the transverse section 17 and on the base 14 and sidewall 15 of the plurality of longitudinal trench sections 16 which are located in the active area 18 and in the trench in the edge region 19. At this stage of the process, the first sublayer 60 has a uniform thickness throughout the edge region 19 and active area 18.

Referring to FIG. 10A, the dielectric layer 26 with the differing thicknesses is fabricated by forming a first sublayer 60 on the base 14 and sidewall of the transverse trench section 17 and on the base 14 and sidewall 15 of the plurality of longitudinal trench sections 16 which are located in the active area 18 and in the edge region 19. Subsequently, referring to FIG. 10B, a mask 62 is formed on the edge region 19 which covers the edge region 19 and exposes the active area 18. A portion of the first sublayer 60 is selectively removed from the sidewall 14 and base 15 of the active portion 21 of the plurality of longitudinal trench sections 16 that are located in the active area 18 to reduce the thickness of the dielectric layer 26 in the active area 18 compared to the edge region 19, as shown in FIG. 10C. The term “selectively removing” is used herein in an area sense, i.e. the portion of the first sublayer is removed from the side wall 15 and base 14 of the trench structure 13 located in the active area 18 but not from the side wall 15 and base 14 of the trench structure 13 located in the edge region 19. The first sublayer 60 is not removed from the sidewall 15 and base 14 of the end portions of the plurality of longitudinal trench sections 16 which are located in the edge region 19 and is not removed from the base 14 and sidewall 15 of the transverse trench section 17. At this stage in the process, the dielectric layer 26 on the sidewall 15 and base 14 of the plurality of longitudinal trench sections 16 located in the active area 18 has a smaller thickness than in the edge region 19.

To selectively remove at least a portion of the first sublayer 60 in the active area 18, the edge region 19 may be covered and the active area 18 exposed. For example, a mask formed of photoresist can be formed on the first major surface 11 which covers the edge region 19 and has an opening which exposes sections of the longitudinal trench sections 16 that are located in the active area 18. With the edge region 19 covered, the first layer sublayer 60 which is exposed and located in the exposes active area 18 may be etched, for example wet etched.

Referring to FIG. 10D, after the removal of the first sublayer 60 from the side wall 15 and base 14 of the exposed sections of the longitudinal trench sections 16 in the active area 18, the remainder of the first sublayer 60 has a thickness which is less than the desired final thickness t_{act} of the dielectric layer 26 in the active area 18. A second sublayer 61 is then deposited on the first sublayer 60 in the transverse trench section 17 and in the end portion of the plurality of longitudinal trench sections 16 which are located in the edge region 19 and in the active area 18. The difference in the thickness of the dielectric layer 26 in the active area 18 and edge region 19 remains after deposition of the second sublayer 61.

In some embodiments, the first sublayer 60 is removed entirely from the sidewall 15 and base 14 of the plurality of longitudinal trench sections 16 located in the active area 18. In this embodiment, the second sublayer 61 has a thickness which corresponds to the desired thickness t_{act} of the dielectric layer 26 in the active area 18.

Referring to FIG. 10E, conductive material, e.g. phosphorous-doped polysilicon (n-type polysilicon), is then deposited into the trench structure 13 to form the field plate 22 in the trench structure 13. The trench structure 13 may be filled with the conductive material to form the field plate.

In some embodiments, as shown in FIG. 10F, a gate electrode 68 is formed in an upper part of the trench structure 13. The field plate 22 has a smaller height and is located at the base of the trench structure 13. The field plate 22 is then covered by an intermediate dielectric layer 66. A gate dielectric 67 is formed on the side wall 15 of the trench structure 13 in the upper portion of the trench structure 13 and then the conductive material of the gate electrode 68 is inserted into the trench structure 13 and the electrically conductive gate electrode 68 is formed on the intermediate dielectric layer 66.

In an alternative non-illustrated embodiment, the dielectric layer 26 may be formed by forming a first sublayer 60 on the base 14 and sidewall 15 of the transverse trench section 17 and on the base 14 and sidewall 15 of the plurality of longitudinal trench section 16 which are located in the active area 18 and in the edge region 19. A second sublayer 61 may then be deposited on the first sublayer 60 which is located in the transverse trench section 17 and in the plurality of longitudinal trench sections 16 which are located in the edge region 19 and in the active area 18. At this stage in the process, the thickness of the combination of the first sublayer 60 and the second sublayer 61 is substantially uniform throughout the active area 18 and the edge region 19. Then, a portion of the second sublayer 61 is selectively removed from the side wall 15 and base 14 of the plurality of longitudinal trench section 16 which are located in the active area 18.

The portion of the second sublayer 61 is not removed from the sidewall 15 and base 14 of the transverse trench section 17 and the end portions of the plurality of longitudinal trench section 16 which are located in the edge region 19. For example, the edge region 19 may be covered and the active area 18 exposed. For example, a mask formed of photoresist can be formed on the first major surface 11 which covers the edge region 19 and which has an opening which exposes the active area 18. A portion of the second sublayer 61 may be etched away from the sidewalls 15 and base 14 of the plurality of longitudinal trench sections 16 which are located in the exposed active area 18. This reduces the thickness of the dielectric layer 26 in the active area 18 to the thickness t_{act}, compared to the thickness t_{end} in the edge region 19. A wet etch may be used.

In an alternative embodiment, which is not illustrated in the drawings, the first sublayer 60 is a deposited layer rather than a thermally gown oxide layer and a second sublayer 61 is selectively deposited on the first sublayer 60 in the transverse trench section 17 and in the end portions of the plurality of longitudinal trench sections 16 that are located in the edge region. Selectively depositing refers to a spatially (areally) selective deposition of the second sublayer in a defined region, namely the edge region 19, and not in the active area 18. For example, the second sublayer 61 may be selectively deposited by covering the active area 18, for example using a mask, e.g. a photoresist mask, whereby the mask exposes the edge region 19. With the active area covered, the second sublayer 61 is deposited on the first sublayer 60 in the exposed edge region 19 and therefore onto the base 14 and sidewall 15 of the transverse trench section 17 and onto the base 14 and sidewalls 15 in the end portions of the plurality of longitudinal trench sections 16 which are located in the edge region 19.

Although the present disclosure is not so limited, the following numbered examples demonstrate one or more aspects of the disclosure.
1. A semiconductor device, comprising:
   i. a semiconductor substrate comprising a first major surface, an active area and an edge region that laterally surrounds the active area;
   ii. a trench structure formed in the first major surface and comprising a base, sidewalls, a transverse trench section and a plurality of longitudinal trench sections, wherein the transverse trench section is located in the edge region and the plurality of longitudinal trench sections extend from the transverse trench section into the active area,
   iii. wherein the trench structure comprises a field plate that is electrically insulated from the semiconductor substrate by a dielectric layer located on the base and the side walls of the trench structure,
   iv. wherein the dielectric layer has a thickness t_{end} on the side walls in an end portion of the longitudinal trench sections which is located in the edge region and has a thickness t_{act} on the side walls in a portion of the longitudinal trench sections which is located in the active area, wherein t_{end} is greater than t_{act}.
2. A semiconductor device according to example 1, wherein the plurality of longitudinal trench sections meet the transverse trench section at an angle of about 90°, forming a T-shape.
3. A semiconductor device according to example 1 or example 2, wherein the longitudinal trench sections and the transverse trench section are elongated and stripe-like.
4. A semiconductor device according to any one of examples 1 to 3, wherein the longitudinal trench sections have an end section that adjoins the transverse section, wherein the end section and the transverse section have a width that is wider than a central portion of the longitudinal trench sections.
5. A semiconductor device according to any one of examples 1 to 3, wherein the longitudinal trench sections extend substantially parallel to one another.
6. The semiconductor device according to any one of examples 1 to 5, wherein t_{end} and t_{act} are measured at a distance dₘ from the base of the trench structure, the distance dₘ being ⅓ of the depth d of the trench structure.
7. The semiconductor device according to any one of examples 1 to 6, wherein 105% t_{act}≤t_{end}≤125% t_{act}.
8. The semiconductor device according to example 7, wherein 110% t_{act}≤t_{end}≤120% t_{act}.
9. The semiconductor device according to any one of examples 1 to 8, wherein 5 nm≤(t_{end}−t_{act})≤40 nm.
10. The semiconductor device according to example 9, wherein 10 nm≤(t_{end}−t_{act})≤15 nm.
11. The semiconductor device according to any one of examples 1 to 10, wherein the dielectric layer located on the side walls of the transverse trench section has the thickness t_{end}.
12. The semiconductor device according to any one of examples 1 to 11, wherein a mesa is formed between the side walls of two neighbouring ones of the plurality of longitudinal trench sections and the mesa has an end face that is bounded a portion of the side wall transverse trench section.
13. The semiconductor device according to any one of examples 1 to 8, wherein the trench structure further comprises a gate electrode that is positioned in the trench structure above the field plate and that is electrically insulated from the field plate.
14. The semiconductor device according to any one of examples 1 to 12, wherein the semiconductor substrate has a first conductivity type and the semiconductor device further comprises, in the active area, a source region of the first conductivity type, a body region of a second conductively type that opposes the first conductivity type and a drain region of the first conductivity type formed at a second major surface of the semiconductor substrate that opposes the first major surface, wherein the edge region is free of the source region.
15. A semiconductor device, comprising:
   i. a semiconductor substrate comprising a first major surface, an active area and an edge region that laterally surrounds the active area;
   ii. a trench structure formed in the first major surface and comprising a base, sidewalls, a transverse trench section and a plurality of longitudinal trench sections, wherein the transverse trench section is located in the edge region and the plurality of longitudinal trench sections extend from the transverse trench section into the active area,
   iii. wherein the trench structure comprises a field plate that is electrically insulated from the semiconductor substrate by a dielectric layer located on the base and the side walls of the trench structure,
   iv. wherein the semiconductor substrate has a first conductivity type and a doping level of X of 1×10¹⁶·cm⁻³ to 2×10¹⁷ cm⁻³ in the active region and comprises a doped region of the first conductivity type that has a doping level Y of 1×10¹⁶ cm⁻³ to 2×10¹⁷cm⁻³, wherein the doped region is located adjacent a lower half of an end portion of the plurality of longitudinal trench sections, the end portion being located in the edge region, wherein 115% X≤Y≤135% X.
16. A semiconductor device according to example 15, wherein the semiconductor substrate is formed of an epitaxial layer.
17. A semiconductor device according to example 15 or example 16, wherein the epitaxial layer is located on a base substrate and the base substrate has a higher doping level that the epitaxial layer.
18. A semiconductor device according to any one of examples 15 to 17, wherein the doped region is located under the base of the end portion of the plurality of longitudinal trench sections that is located in the edge region, wherein 115% X≤Y≤135% X.
19. A semiconductor device according to example 18, wherein the doped region is located adjacent a lower half of the side wall of the end portion of the plurality of longitudinal trench sections that is located in the edge region, wherein 115% X≤Y≤135% X.
20. The semiconductor device according to example 19, wherein 120% X≤Y≤125% X.
21. The semiconductor device according to any one of examples 15 to 20, wherein the doped region is further arranged under the base of the transverse trench section.
22. The semiconductor device according to any one of examples 15 to 21, wherein the doped region is further arranged in the mesa adjacent the lower portion of the side walls of the neighbouring ones of the plurality of longitudinal trench sections.
23. The semiconductor device according to any one of examples 15 to 22, wherein a mesa is formed between the side walls of two neighbouring ones of the plurality of longitudinal trench sections and the mesa has an end face that is bounded a portion of the side wall transverse trench section.
24. The semiconductor device according to example 23, wherein the doped region is further arranged in the end face of the mesa.
25. The semiconductor device according to anyone of examples 15 to 24, wherein the dielectric layer has a thickness t_{end} on the side walls in an end portion of the longitudinal trench sections which is located in the edge region and has a thickness t_{act} on the side walls in a portion of the longitudinal trench sections which is located in the active area, wherein t_{end} is greater than t_{act}.
26. The semiconductor device according to example 25, wherein t_{end} and t_{act} are measured at a distance dₘ from the base of the trench structure, the distance dₘ being ⅓ of the depth d of the trench structure.
27. The semiconductor device according to example 25 or example 26, wherein 105% t_{act}≤t_{end}≤125% t_{act}.
28. The semiconductor device according to example 27, wherein 110% t_{act}≤t_{end}≤120% t_{act}.
29. The semiconductor device according to any one of examples 25 to 28, wherein 5 nm≤(t_{end}−t_{act})≤40 nm.
30. The semiconductor device according to example 29, wherein 10 nm≤(t_{end}−t_{act})≤15 nm.
31. The semiconductor device according to any one of examples 25 to 30, wherein the dielectric layer located on the side walls of the transverse trench section has the thickness t_{end}.
32. The semiconductor device according to any one of examples 25 to 31, wherein the trench structure further comprises a gate electrode that is positioned in the trench structure above the field plate and that is electrically insulated from the field plate.
33. A method comprising:
   i. forming a trench structure in a first surface of a semiconductor substrate comprising an active area and an edge region that laterally surrounds the active area, wherein the trench structure comprising a base, sidewalls, a transverse trench section and a plurality of longitudinal trench sections, wherein the transverse trench section is located in the edge region and the plurality of longitudinal trench sections extend from the transverse trench section into the active area,
   ii. forming a dielectric layer on the base and the side walls of the plurality of longitudinal trench sections and the transverse trench section with a thickness t_{end} on the side walls in end portions of the longitudinal trench sections which are located in the edge region and a thickness t_{act} on the side walls in portions of the longitudinal trench sections which are located in the active area, wherein t_{end} is greater than t_{act}.
34. A method according to claim 33, wherein the thickness of the dielectric layer is measured at a distance dₘ from the base of the trench, the distance dₘ being ⅓ of the depth d of the trench.
35. The method of example 33 or example 34, wherein the forming the dielectric layer comprises: forming a first sublayer on the base and side wall of the transverse trench section and on the base and side wall of the plurality longitudinal trench sections located in the active area and in the edge region; selectively depositing a second sublayer on the first sublayer in the transverse trench section and in the end portions of the plurality of longitudinal trench sections located in the edge region.
36. The method of example 35, wherein the selectively depositing a second sublayer comprises: covering the active area and exposing the edge region, and depositing the second sublayer on the first sublayer in the transverse trench section and in the end portions of the plurality of longitudinal trench sections located in the edge region.
37. The method according to example 33, wherein the forming the dielectric layer comprises: forming a first sublayer on the base and side wall of the transverse trench section and on the base and side wall of the plurality of longitudinal trench sections located in the active area and in the edge region, then selectively removing a portion of the first sublayer from the side wall and the base of the plurality of longitudinal trench sections located in the active area, and then depositing a second sublayer on the first sublayer in the transverse trench section and in the plurality of longitudinal trench sections located in the edge region and in the active area.
38. The method according to example 37, wherein the selectively removing a portion of the first sublayer in the active area comprises: covering the edge region and exposing the active area, and etching the first sublayer in the exposed active area.
39. The method according to example 33, wherein the forming the dielectric layer comprises: forming a first sublayer on the base and side wall of the transverse trench section and on the base and side wall of the plurality of longitudinal trench sections located in the active area and in the edge region; depositing a second sublayer on the first sublayer in the transverse trench section and in the plurality of longitudinal trench sections located in the edge region and in the active area; selectively removing a portion of the second sublayer from the side walls and the base of the plurality of longitudinal trench sections located in the active area.
40. The method according to example 39, wherein the selectively removing a portion of the second sublayer in the active area comprises: covering the edge region and exposing the active area, and etching a portion of the second sublayer from the side walls and the base of the plurality of longitudinal trench sections located in the exposed active area.
41. The method according to any one of examples 33 to 40, wherein 105% t_{act}≤t_{end}≤125% t_{act} or 110% t_{act}≤t_{end}≤120% t_{act}.
42. The method according to any one of examples 33 to 32, wherein 5 nm ≤(t_{end}−t_{act})≤40 nm or 10 nm≤(t_{end}−t_{act})≤15 nm.
43. The method according to any one of examples 33 to 42, further comprising inserting conductive material into the trench structure and forming a field plate in the plurality of longitudinal trench sections and in the transverse trench section.
44. The method according to example 43, further comprising forming a gate electrode in the trench structure above the field plate.
45. a Method Comprising:
   i. forming a trench structure in a first surface of a semiconductor substrate of a first conductivity type comprising an active area and an edge region that laterally surrounds the active area, wherein the trench structure comprising a base, sidewalls, a transverse trench section and a plurality of longitudinal trench sections, wherein the transverse trench section is located in the edge region and the plurality of longitudinal trench sections extend from the transverse trench section into the active area;
   ii. selectively Implanting dopants of the first conductivity type into the base of the transverse trench section and into the base of the end portion of the plurality of longitudinal trench sections located in the edge region and forming a doped region of the first conductivity type.
46. The method according to example 45, wherein the semiconductor substrate has a doping level X of 1×10¹⁶·cm⁻³ to 2×10¹⁷ cm⁻³ in the active region and comprises a doped region of the first conductivity type that has a doping level Y of 1×10¹⁶ cm⁻³ to 2×10¹⁷cm⁻³, wherein the doped region is located adjacent a lower half of an end portion of the plurality of longitudinal trench sections, the end portion being located in the edge region, wherein 115% X≤Y≤135%.
47. the Method According to Example 45 or Example 46, Wherein 120% X≤Y≤125% X.
48. The method according to any one of examples 45 to 47, wherein the dopants are implanted at 0° tilt or up to 20° tilt to the first major surface.
49. The method according to any one of examples 45 to 48, wherein the dopants are further implanted into a lower portion of the side wall of the end section of the plurality of longitudinal trench sections and/or the base of the end section of the plurality of longitudinal trench sections.
50. The method according to any one of examples 45 to 49, wherein a mesa is formed between the side faces of neighbouring ones of the plurality of longitudinal trenches and by the transverse trench section and the doped region is arranged in the mesa adjacent the lower portion of the side walls and below the base of the neighbouring ones of the plurality of longitudinal trench sections.
51. The method according to any one of examples 45 to 49, wherein the doped region in the transverse trench section has a lateral extent such that it is located in at least one and up to six neighbouring mesas.
52. The method according to any one of examples 45 to 51, wherein the doped region is further arranged in a lower portion of an end face of the mesa that is formed by the side wall of the transverse trench section and under the base of the transverse trench section that adjoins said side wall of the transverse trench section.
53. The method of any one of examples 43 to 52, further comprising: forming a dielectric layer on the base and the side walls of the transverse trench section and of the plurality of longitudinal trench sections located in the active area and in the edge region; inserting conductive material into the plurality of longitudinal trench sections and into the transverse trench section to form a field plate.
54. The method of example 53, further comprising: forming an intermediate dielectric layer on the field plate; forming a gate oxide on the side walls of the trench structure, and forming a gate electrode in the trench structure above the field plate.
55. The method according to example 53 or example 54, wherein the forming a dielectric layer on the base and the side walls of the plurality of longitudinal trench sections and the transverse trench section comprises: forming a dielectric layer with a thickness t_{end} on the side walls in end portions of the longitudinal trench sections which are located in the edge region and a thickness t_{act} on the side walls in portions of the longitudinal trench sections which are located in the active area, wherein t_{end} is greater than t_{act}.
56. The method of example 55, wherein the forming the dielectric layer comprises: forming a first sublayer on the base and side wall of the transverse trench section and on the base and side wall of the plurality longitudinal trench sections located in the active area and in the edge region; selectively depositing a second sublayer on the first sublayer in the transverse trench section and in the end portions of the plurality of longitudinal trench sections located in the edge region.
57. The method of example 56, wherein the selectively depositing a second sublayer comprises: covering the active area and exposing the edge region, and depositing the second sublayer on the first sublayer in the transverse trench section and in the end portions of the plurality of longitudinal trench sections located in the edge region.
58. The method according to example 55, wherein the forming the dielectric layer comprises: forming a first sublayer on the base and side wall of the transverse trench section and on the base and side wall of the plurality of longitudinal trench sections located in the active area and in the edge region, then selectively removing a portion of the first sublayer from the side wall and the base of the plurality of longitudinal trench sections located in the active area, and then depositing a second sublayer on the first sublayer in the transverse trench section and in the plurality of longitudinal trench sections located in the edge region and in the active area.
59. The method according to example 58, wherein the selectively removing a portion of the first sublayer in the active area comprises: covering the edge region and exposing the active area, and etching the first sublayer in the exposed active area.
60. The method according to example 55, wherein the forming the dielectric layer comprises: forming a first sublayer on the base and side wall of the transverse trench section and on the base and side wall of the plurality of longitudinal trench sections located in the active area and in the edge region; depositing a second sublayer on the first sublayer in the transverse trench section and in the plurality of longitudinal trench sections located in the edge region and in the active area; selectively removing a portion of the second sublayer from the side walls and base of the plurality of longitudinal trench sections located in the active area.
61. The method according to example 60, wherein the selectively removing a portion of the second sublayer in the active area comprises: covering the edge region and exposing the active area, and etching a portion of the second sublayer from the side walls and base of the plurality of longitudinal trench sections located in the exposed active area.
62. The method according to any one of examples 33 to 61, further comprising inserting conductive material into the trench structure and forming a field plate in the plurality of longitudinal trench sections and in the transverse trench section.
63. The method according to example 62, further comprising forming a gate electrode in the trench structure above the field plate.
64. The method according to any one of examples 55 to 63, wherein 105% t_{act}≤t_{end}≤125% t_{act} or 110% t_{act}≤t_{end}≤120% t_{act}.
65. The method according to any one of examples 55 to 64, wherein 5 nm≤(t_{end}−t_{act})≤40 nm or 10 nm≤(t_{end}−t_{act})≤15 nm.

Three approaches are described herein for the implementation of the termination engineering, namely n+ phosphorous implantation at the termination region, the engineering of a thicker FOX at the termination and the combination of the above mentioned.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor device, comprising:
a semiconductor substrate comprising a first major surface, an active area, and an edge region that laterally surrounds the active area;
a trench structure formed in the first major surface and comprising a base, a plurality of sidewalls, a transverse trench section, and a plurality of longitudinal trench sections, wherein the transverse trench section is located in the edge region and the longitudinal trench sections extend from the transverse trench section into the active area,
wherein the trench structure further comprises a field plate that is electrically insulated from the semiconductor substrate by a dielectric layer located on the base and the side walls of the trench structure,
wherein the dielectric layer has a thickness t_{end} on the side walls in an end portion of the longitudinal trench sections which is located in the edge region and has a thickness t_{act} on the side walls in a portion of the longitudinal trench sections which is located in the active area,
wherein t_{end} is greater than t_{act}.

2. The semiconductor device of claim 1, wherein t_{end} and t_{act} are measured at a distance dₘ from the base of the trench structure, the distance dₘ being ⅓ of the depth d of the trench structure.

3. The semiconductor device of claim 1, wherein 105% t_{act}≤t_{end}≤125% t_{act}.

4. The semiconductor device of claim 3, wherein 110% t_{act}≤t_{end}≤120% t_{act}.

5. The semiconductor device of claim 1, wherein 5 nm≤(t_{end}−t_{act})≤40 nm.

6. The semiconductor device of claim 5, wherein 10 nm≤(t_{end}−t_{act})≤15 nm.

7. The semiconductor device of claim 1, wherein the dielectric layer located on the side walls of the transverse trench section has the thickness t_{end.}

8. The semiconductor device of claim 1, wherein a mesa is formed between the side walls of two neighbouring ones of the longitudinal trench sections and the mesa has an end face that is bounded by a portion of the side wall of the transverse trench section.

9. The semiconductor device of claim 1, wherein the trench structure further comprises a gate electrode that is positioned in the trench structure above the field plate and that is electrically insulated from the field plate.

10. The semiconductor device of claim 1, wherein the semiconductor substrate has a first conductivity type and the semiconductor device further comprises, in the active area, a source region of the first conductivity type, a body region of a second conductively type that opposes the first conductivity type, and a drain region of the first conductivity type formed at a second major surface of the semiconductor substrate that opposes the first major surface, and wherein the edge region is free of the source region.

11. A semiconductor device, comprising:
a semiconductor substrate comprising a first major surface, an active area, and an edge region that laterally surrounds the active area;
a trench structure formed in the first major surface and comprising a base, a plurality of sidewalls, a transverse trench section, and a plurality of longitudinal trench sections, wherein the transverse trench section is located in the edge region and the longitudinal trench sections extend from the transverse trench section into the active area,
wherein the trench structure further comprises a field plate that is electrically insulated from the semiconductor substrate by a dielectric layer located on the base and the side walls of the trench structure,
wherein the semiconductor substrate has a first conductivity type and a doping level X of 1×10¹⁶ cm⁻³ to 2×10¹⁷ cm⁻³ in the active region and comprises a doped region of the first conductivity type that has a doping level Y of 1×10¹⁶ cm⁻³ to 2×10¹⁷ cm⁻³,
wherein the doped region is located adjacent a lower half of an end portion of the plurality of longitudinal trench sections, the end portion being located in the edge region,
wherein 115% X≤Y≤135% X.

12. The semiconductor device of claim 11, wherein 120% X≤Y≤125% X.

13. The semiconductor device of claim 11, wherein the doped region is further arranged under the base of the transverse trench section.

14. The semiconductor device of claim 11, wherein the doped region is further arranged in a mesa adjacent the lower portion of the side walls of the neighbouring ones of the longitudinal trench sections.

15. The semiconductor device of claim 11, wherein a mesa is formed between the side walls of two neighbouring ones of the longitudinal trench sections and the mesa has an end face that is bounded a portion of the side wall of the transverse trench section.

16. The semiconductor device of claim 15, wherein the doped region is further arranged in the end face of the mesa.

17. A method, comprising:
forming a trench structure in a first surface of a semiconductor substrate comprising an active area and an edge region that laterally surrounds the active area, wherein the trench structure comprises a base, a plurality of sidewalls, a transverse trench section, and a plurality of longitudinal trench sections, wherein the transverse trench section is located in the edge region and the longitudinal trench sections extend from the transverse trench section into the active area;
forming a dielectric layer on the base and the side walls of the longitudinal trench sections and the transverse trench section with a thickness t_{end} on the side walls in end portions of the longitudinal trench sections which are located in the edge region and a thickness t_{act} on the side walls in portions of the longitudinal trench sections which are located in the active area, wherein t_{end} is greater than t_{act}.

18. The method of claim 17, wherein forming the dielectric layer comprises:
forming a first sublayer on the base and the side walls of the transverse trench section and on the base and the side walls of the longitudinal trench sections located in the active area and in the edge region;
selectively depositing a second sublayer on the first sublayer in the transverse trench section and in the end portions of the longitudinal trench sections located in the edge region.

19. The method of claim 17, wherein forming the dielectric layer comprises:
forming a first sublayer on the base and the side walls of the transverse trench section and on the base and the side walls of the longitudinal trench sections located in the active area and in the edge region;
then selectively removing a portion of the first sublayer from the side walls and the base of the longitudinal trench sections located in the active area; and
then depositing a second sublayer on the first sublayer in the transverse trench section and in the longitudinal trench sections located in the edge region and in the active area.

20. The method of claim 19, wherein selectively removing a portion of the first sublayer in the active area comprises:
covering the edge region and exposing the active area; and
etching the first sublayer in the exposed active area.

21. The method of claim 17, wherein forming the dielectric layer comprises:
forming a first sublayer on the base and the side walls of the transverse trench section and on the base and the side walls of the longitudinal trench sections located in the active area and in the edge region;
depositing a second sublayer on the first sublayer in the transverse trench section and in the longitudinal trench sections located in the edge region and in the active area; and
selectively removing a portion of the second sublayer from the side walls and the base of the longitudinal trench sections located in the active area.

22. The method of claim 21, wherein selectively removing a portion of the second sublayer in the active area comprises:
covering the edge region and exposing the active area; and
etching a portion of the second sublayer from the side walls and the base of the longitudinal trench sections located in the exposed active area.

23. A method, comprising:
forming a trench structure in a first surface of a semiconductor substrate of a first conductivity type comprising an active area and an edge region that laterally surrounds the active area, wherein the trench structure comprises a base, sidewalls, a transverse trench section, and a plurality of longitudinal trench sections, wherein the transverse trench section is located in the edge region and the longitudinal trench sections extend from the transverse trench section into the active area; and
selectively implanting dopants of the first conductivity type into the base of the transverse trench section and into the base of an end portion of the plurality of longitudinal trench sections located in the edge region and forming a doped region of the first conductivity type.

24. The method of claim 23, wherein the semiconductor substrate has a doping level X of 1×10¹⁶ cm⁻³ to 2×10¹⁷ cm⁻³ in the active region and comprises the doped region of the first conductivity type that has a doping level Y of 1×10¹⁶ cm⁻³ to 2×10¹⁷ cm⁻³, wherein the doped region is located adjacent a lower half of the end portion of the plurality of longitudinal trench sections, and wherein 115% X≤Y≤135%.
